(19) United States
(12) Patent Application Publication
(10) Pub. No.: US 2026/0025952 A1
(43) Pub. Date: Jan. 22, 2026

(54) COMPOSITE HEAT DISSIPATION ASSEMBLY

(71) Applicant: COOLER MASTER TECHNOLOGY INC., Taipei City (TW)

(72) Inventor: Jen-Chih CHENG, Taipei City (TW)

(21) Appl. No.: 19/265,007

(22) Filed: Jul. 10, 2025

(30) Foreign Application Priority Data
Jul. 19, 2024 (TW) 113207773

(51) Int. Cl. H05K 7/20; F28F 13/12; G06F 1/20

(52) U.S. Cl. CPC H05K 7/20336; F28F 13/125; G06F 1/206; F28F 2215/00; F28F 2250/08

(57) ABSTRACT

A composite heat dissipation assembly includes an air-cooling heat dissipation device having a thermal conductive base and a plurality of heat pipes, the plurality of heat pipes are disposed on the thermal conductive base, the thermal conductive base includes a first joint on a top side and is configured to be thermally coupled to a heat source on a bottom side opposite to the top side, a liquid-cooling heat dissipation device having a liquid block, the liquid block includes a second joint on a bottom side and is configured to be attached to the first joint so that the liquid block is thermally coupled to the thermal conductive base and a position limiter disposed at a position where the first joint is coupled to the second joint so that relative movement between the air-cooling heat dissipation device and the liquid-cooling heat dissipation device.

### RELATED APPLICATIONS

This US application claims priority to Taiwan application No. 113207773, filed on Jul. 19, 2024, which is incorporated herein by reference in its entirety.

### TECHNICAL FIELD

The present disclosure is related to the field of heat dissipation devices, in particular a composite heat dissipation device.

### BACKGROUND

As processor performance improves, the heat generated by the processor also increases. If the generated heat accumulates within the electronic device, its performance and lifespan of the electronic device may be compromised. Thus, the demand for efficient heat dissipation has been increased over time as the performance of electronic devices, particularly computers, has advanced.

Conventional heat dissipation mechanisms generally use air cooling or liquid cooling. The former utilizes a fan to blow air onto heat dissipation fins that are thermally coupled to a heat source, dissipating the heat generated by the heat source. The latter employs a circulating liquid cooling system comprised of a liquid block, radiator, and pump; a cooling fluid absorbs heat from the heat source via the liquid block. However, any of these two cooling techniques may only be effective for dissipating heat from a single heat source; with multiple heat sources, the effectiveness of heat dissipation by either air cooling or liquid cooling remains to be enhanced. Therefore, there is still a need for better cooling solutions for electronic devices, particularly those with multiple heat sources.

### SUMMARY

Aspects of the disclosure provide a composite heat dissipation assembly. The assembly includes an air-cooling heat dissipation device having a thermal conductive base and a plurality of heat pipes, the plurality of heat pipes are disposed on the thermal conductive base, the thermal conductive base includes a first joint on a top side and is configured to be thermally coupled to a heat source on a bottom side opposite to the top side, a liquid-cooling heat dissipation device having a liquid block, the liquid block includes a second joint on a bottom side and is configured to be attached to the first joint for allowing the liquid block to be thermally coupled to the thermal conductive base, and a position limiter disposed at a position where the first joint is secured to the second joint for restricting relative movements between the air-cooling heat dissipation device and the liquid-cooling heat dissipation device.

In an embodiment, the position limiter can further include two plates and a plurality of screws, the plates are respectively fastened to opposite sides of the thermal conductive base via the screws along a removable movement axis of the second joint relative to the first joint, and the plates abut the second joint in the removeable movement axis to limit relative movements between the thermal conductive base and the liquid block along the removable movement axis.

In an embodiment, the position limiter can include at least one screw configured to fasten through the first joint to the second joint.

In an embodiment, the first joint can be a groove structure and the second joint can be a protrusion structure. In an example, the first joint can be a dovetail groove and the second joint can be a dovetail protrusion.

In an embodiment, the liquid-cooling heat dissipation device can further include a plurality of fins that are disposed on the bottom side of the liquid block.

In an embodiment, the heat pipe is disposed through the thermal conductive base and extends away from the thermal conductive base. In some embodiments, the air-cooling heat dissipation device can further include a fan connected to the heat pipe at an end away from the thermal conductive base.

In an embodiment, the liquid-cooling heat dissipation device can further include a radiator that is connected to the liquid block and forms a liquid-cooling cycle with the liquid block. In some embodiments, the liquid-cooling heat dissipation device can further include a fan that is disposed on the radiator.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of a composite heat dissipation assembly 100 according to aspects of the present disclosure.

FIG. 2 illustrates a perspective view of the decomposition of the composite heat dissipation assembly 100 as shown in FIG. 1.

FIG. 3 illustrates a perspective view of a partial enlargement of the composite heat dissipation assembly 100 as shown in FIG. 1.

FIG. 4 illustrates a cross-section view of the partial enlargement of the composite heat dissipation assembly 100 in FIG. 1.

FIG. 5 illustrates a cross-section view of the partial enlargement of the composite heat dissipation assembly 200 according to aspects of the present disclosure.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

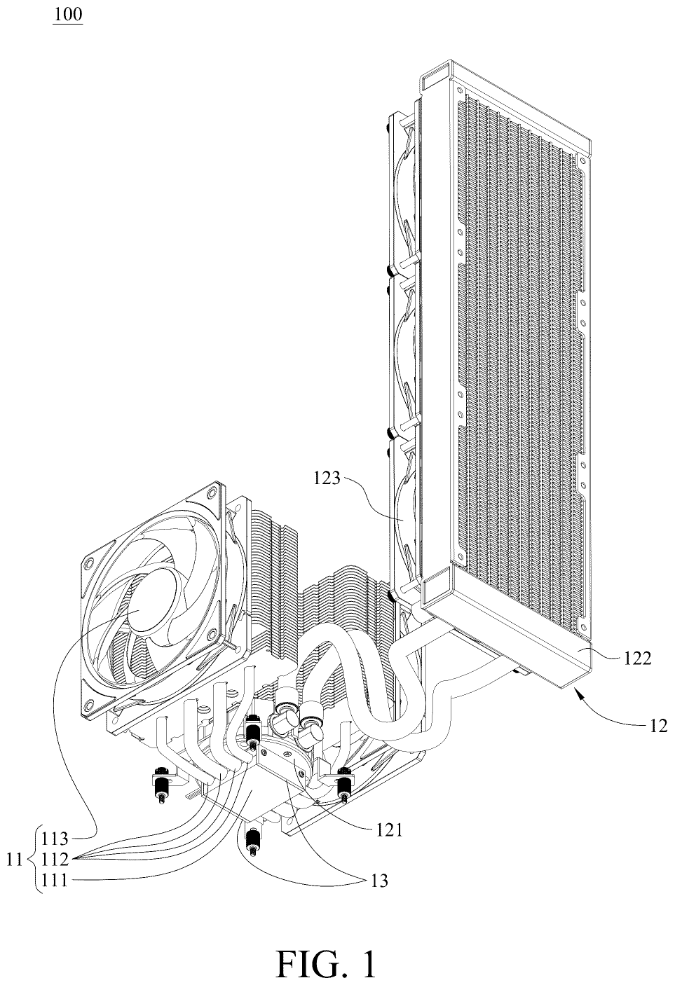

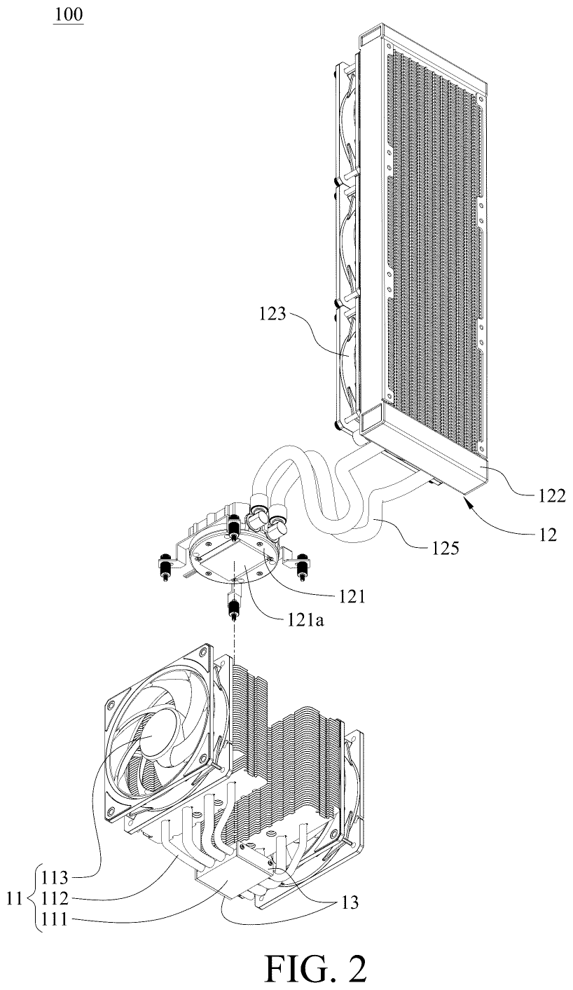

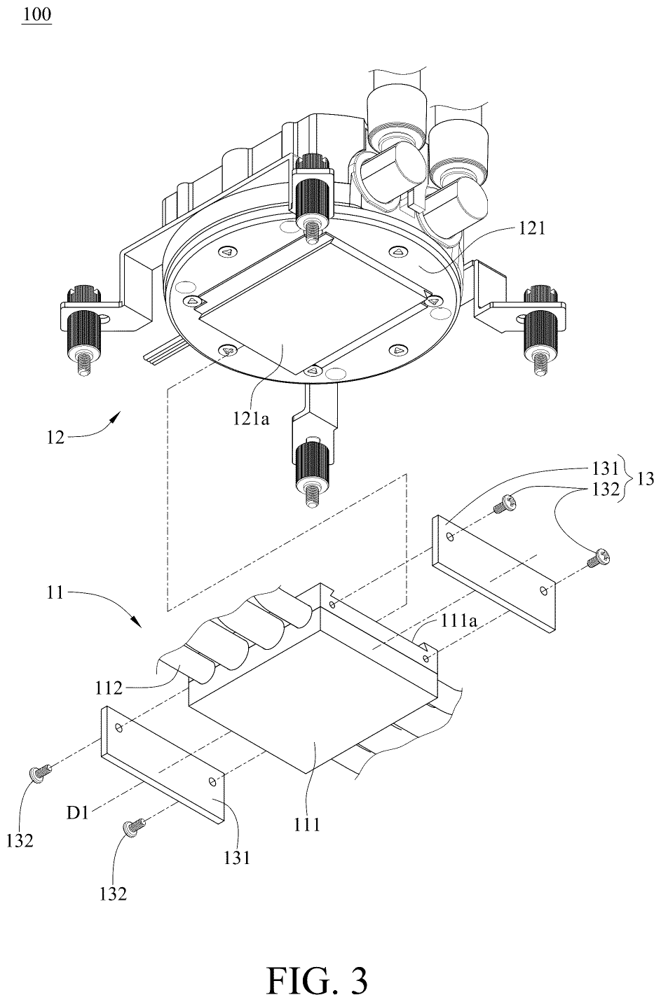

Please refer to FIG. 1 to FIG. 3. FIG. 1 illustrates a perspective view of a composite heat dissipation assembly 100 according to aspects of the present disclosure. FIG. 2 illustrates a perspective view of the decomposition of the composite heat dissipation assembly 100 as shown in FIG. 1. FIG. 3 illustrates a s perspective view of a partial enlargement of the composite heat dissipation assembly 100 as shown in in FIG. 1.

The composite heat dissipation assembly 100 includes an air-cooling heat dissipation device 11 and a liquid-cooling heat dissipation device 12. The air-cooling heat dissipation device 11 can include a thermal conductive base 111, a plurality of heat pipes 112 and a plurality of fans 113. The thermal conductive base 111 can be used to thermally couple to a heat source, such as a central processing unit (CPU) or a graphics processing unit (GPU) (not shown). The thermal conductive base can absorb the heat generated by the heat source during operation. The heat pipes 112 can be dispose on the thermal conductive base 111 and extend in a direction away from the thermal conductive base 111, allowing the absorbed heat to dissipate from the heat source. The fans 113 can be positioned at the other end of the heat pipes 112 that is not disposed on the thermal conductive base 111. The fans 113 can facilitate air flow to the heat pipes 112, dissipating the heat generated by the heat source.

The liquid-cooling heat dissipation device 12 can include a liquid-cooling block 121, a radiator 122, and a plurality of fans 123. The liquid-cooling block 121 is thermally coupled to the thermal conductive base 111 to assist in absorbing the heat from the heat source. The radiator 122 can be connected to the liquid-cooling block 121 via pipes 125. A cooling fluid, such as water or coolant (not shown) is filled in the liquid-cooling heat dissipation device 12. The cooling fluid flows via the liquid-cooling block 121, the radiator 122, and the pipes 125 to complete a cooling cycle. The fans 123 can be attached to the radiator 122 to facilitate air flow, enhancing the heat dissipation efficiency of the liquid-cooling heat dissipation device 12.

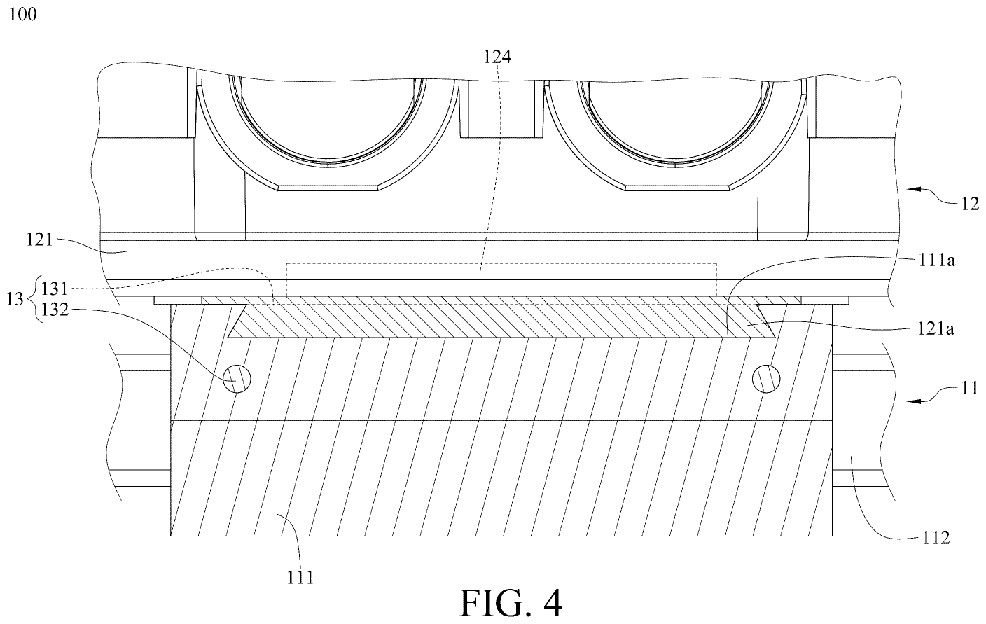

Please also refer to FIG. 4, which illustrates a cross-section view of the partial enlargement of the composite heat dissipation assembly 100 in FIG. 1. The liquid-cooling heat dissipation device 12 may include a plurality of heat sinks 124. The heat sinks 124 can be disposed on a surface of the liquid-cooling block 121, which is coupled to the thermal conductive base 111. The heat sinks 124 are parallel to one another. The heat sinks 124 can transfer the heat from the liquid-cooling block 121 to the radiator 122. Because the size of the heat sinks 124 are often very small, welding the liquid-cooling block 121 with the thermal conductive base 111 may deform the heat sinks 124 under high welding temperature, thereby compromising the heat transfer efficiency of the composite heat dissipation assembly 100.

The thermal conductive base 111 includes a first joint 111a. As shown in FIG. 3 and FIG. 4, the first joint 111a could be shaped such as a dovetail groove. The liquid block 121 has a second joint 121a. As shown in FIG. 3 and FIG. 4, the second joint 121a can be shaped such as a dovetail protrusion. The second joint 121a can be detached and attached with the first joint 111a along a moving axis D1. In addition, the movement of the second joint 121a relative to the first joint 111a in directions perpendicular to the axis D1 can be restricted by the dovetail joints.

The composite heat dissipation assembly 100 can also include a position limiter 13. The position limiter 13 includes two plates 131 and plurality of screws 132. The plates 131 are respectively secured to the opposite sides of the thermal conductive base 111 by the screws 132 along the axis D1. In this way, after the dovetail joints are joined together, the position limiter 13 can limit the movement of liquid block 121 in the axis D1.

The liquid block 121 can be secured to the thermal conductive base 111 via the first joint 111a, second joint 121a, and the position limiter 13, facilitating the heat exchange between the thermal conductive base 111 and the liquid block 121. This can help to prevent deformation of the heat sink 124 caused by inappropriate bonding methods such as welding. As a result, the composite heat dissipation unit 100 can maintain the energy saving benefits of air-cooling heat dissipation device 11 and the high heat dissipation efficiency of liquid-cooling heat dissipation device 12.

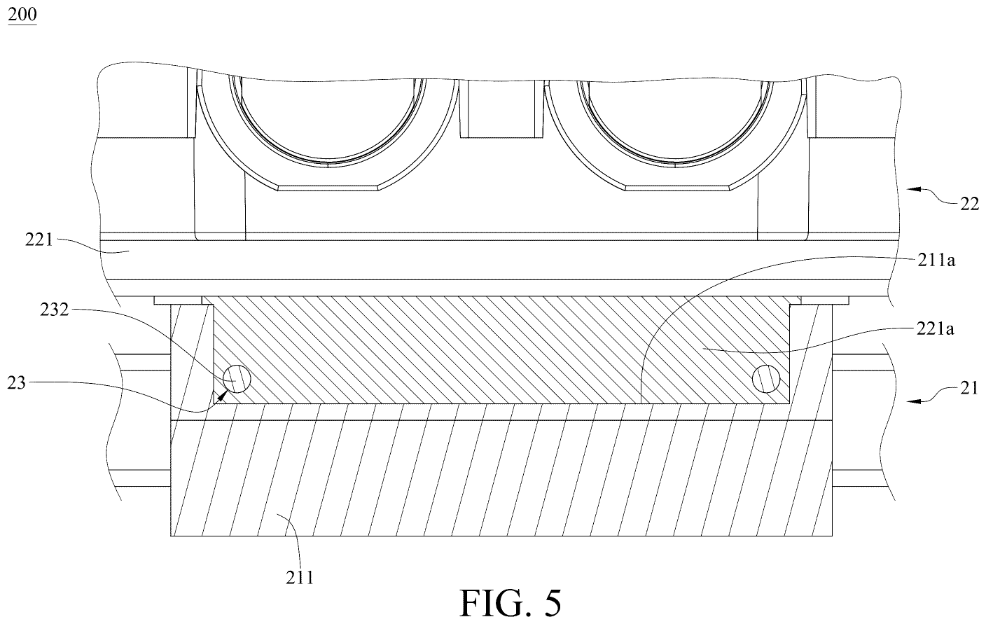

The shapes of the first joint 111a and the second joints 121a are not intended to limit the scope of the present disclosure. Please refer to FIG. 5, which illustrates a cross-section view of the partial enlargement of the composite heat dissipation assembly 200 according to aspects of the present disclosure. The composite heat dissipation assembly 200 disclosed in this embodiment is similar to the composite heat dissipation assembly 100 disclosed in the previous embodiment, thus the following descriptions are limited to the differences, as well as the necessary features.

In this embodiment, the composite heat dissipation assembly 200 includes an air-cooling heat dissipation device 21, a liquid-cooling heat dissipation device 22 and a limiting part 23. The first joint 211a of the air-cooling heat dissipation device 21 can be a straight groove, whereas the second joint 221a of the liquid-cooling heat dissipation device 22 can be a straight convex. The first joint 211a, and the second joint 221a, are structurally concave and convex. The composite heat dissipation assembly 200, like the composite heat dissipation assembly 100, may also include a position limiter 23 and a plurality of screws 232. The position limiter 23 can secure the first joint 211a and the second joint 221a to restrict the relative movement between the thermal conduction base 211 and the liquid block 221. In this way, the air-cooling heat dissipation device 21 can also be coupled to the liquid-cooling heat dissipation device 22.

The shapes of the first joint 211a and the second joints 221a are not intended to limit the scope of the present disclosure. In some other embodiments, the first joint 211a and the second joint 221a can have other shapes that are suitable for the specific application of the composite heat dissipation assembly. For example, the joints can be cross-shape or reversed T-shape, and so forth.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A composite heat dissipation assembly, comprising:
an air-cooling heat dissipation device having a thermal conductive base and a plurality of heat pipes, the plurality of heat pipes are disposed on the thermal conductive base, the thermal conductive base includes a first joint on a top side and is configured to be thermally coupled to a heat source on a bottom side opposite to the top side;
a liquid-cooling heat dissipation device having a liquid block, the liquid block includes a second joint on a bottom side and is configured to be attached to the first joint for allowing the liquid block to be thermally coupled to the thermal conductive base; and
a position limiter disposed at a position where the first joint is secured to the second joint for restricting relative movements between the air-cooling heat dissipation device and the liquid-cooling heat dissipation device.

2. The composite heat dissipation assembly of claim 1, wherein the position limiter further includes two plates and a plurality of screws, the plates are respectively fastened to opposite sides of the thermal conductive base via the screws along a removable movement axis of the second joint relative to the first joint, and the plates abut the second joint in the removeable movement axis to limit relative movements between the thermal conductive base and the liquid block along the removable movement axis.

3. The composite heat dissipation assembly of claim 1, wherein the position limiter includes at least one screw configured to fasten through the first joint to the second joint.

4. The composite heat dissipation assembly of claim 1, wherein the first joint is a groove structure and the second joint is a protrusion structure.

5. The composite heat dissipation assembly of claim 1, wherein the first joint is a dovetail groove and the second joint is a dovetail protrusion.

6. The composite heat dissipation assembly of claim 1, wherein the liquid-cooling heat dissipation device further includes a plurality of fins that are disposed on the bottom side of the liquid block.

7. The composite heat dissipation assembly of claim 1, wherein the heat pipe is disposed through the thermal conductive base and extends away from the thermal conductive base.

8. The composite heat dissipation assembly of claim 7, wherein the air-cooling heat dissipation device further includes a fan connected to the heat pipe at an end away from the thermal conductive base.

9. The composite heat dissipation assembly of claim 1, wherein the liquid-cooling heat dissipation device further includes a radiator that is connected to the liquid block and forms a liquid-cooling cycle with the liquid block.

10. The composite heat dissipation assembly of claim 9, wherein the liquid-cooling heat dissipation device further includes a fan that is disposed on the radiator.
